(19) United States
(12) Patent Application Publication
(10) Pub. No.: US 2025/0112253 A1
(43) Pub. Date: Apr. 3, 2025

(54) POWER DISTRIBUTION UNIT FOR A FUEL CELL SYSTEM, METHOD FOR PRODUCING A POWER DISTRIBUTION UNIT

(71) Applicant: Robert Bosch GmbH, Stuttgart (DE)

(72) Inventors: Markus Feigl, Markgroeningen (DE); Alexander Siegert, Kornwestheim (DE); Jan Tremel, Erlangen (DE)

(21) Appl. No.: 18/728,936

(22) PCT Filed: Jan. 19, 2023
(86) PCT No.: PCT/EP2023/051209

§ 371 Date: Jul. 15, 2024

(30) Foreign Application Priority Data
Jan. 20, 2022 (DE) 10 2022 200 644.5

(51) Int. Cl. H01M 8/0267; B33Y 80/00; H01M 8/0202; H01M 8/04007

(52) U.S. Cl. CPC H01M 8/0267; H01M 8/0269; H01M 8/04007; B33Y 80/00

(57) ABSTRACT

The invention relates to a power distribution unit (1) for a fuel cell system, comprising a housing (2) which has a housing part (3) that forms a cooling duct (4), to which a cooling medium can be applied, and at least one cooling tower (5), extending substantially perpendicularly to the cooling duct (4), for receiving a current-conducting component (6), in particular a bus bar, wherein a cavity (7) is formed in the cooling tower (5) and is connected to the cooling duct (4) such that the cooling medium can also be applied to the cavity (7).

The invention also relates to a method for producing a power distribution unit (1).

### BACKGROUND

The invention relates to a power distribution unit for a fuel cell system, and a method for producing a power distribution unit.

Power distribution units (PDU) are used, for example, in mobile fuel cell systems to connect the fuel cells to an electric machine and/or power electronics to supply electrical power thereto. A PDU is typically equipped with relays, current sensors, bus bars, and resistors and is monitored by software. A PDU is typically connected to the respective electrical consumer by means of high-voltage lines.

A bus bar within a PDU must be cooled due to the high current density. To this end, the bus bar can be screwed onto a so-called cooling tower, which is arranged over a cooling duct, which is milled into a housing bottom of a housing of the PDU and sealed by means of a separate lid including a seal. To optimize the heat conduction and thus heat dissipation, the cooling towers are typically made of aluminum or copper. In order to avoid an electrical short circuit, a thin insulating film is inserted between the cooling tower and the housing. A plastic ring can be provided for short-circuit-free screwing, which is held down with a metal clip and fastened to the housing.

### SUMMARY

Starting from the prior art described above, the present invention is concerned with the task of optimizing the cooling of a current-conducting component, in particular a bus bar, of a PDU. At the same time, the design of a power distribution unit is to be simplified so that it can be produced more cost-effectively.

In order to solve this problem, the power distribution unit according to the disclosure is proposed. Furthermore, a method for producing a power distribution unit is provided.

The power distribution unit proposed for a fuel cell system comprises a housing which has a housing part that forms a cooling duct, to which a cooling medium can be applied, and at least one cooling tower extending substantially perpendicularly to the cooling duct, for receiving a current-conducting component, in particular a bus bar. A cavity is formed in the cooling tower, which is connected to the cooling duct so that the cooling medium can also be applied to the cavity.

The cooling medium can be brought closer to the current-conducting component to be cooled via the cavity formed in the cooling tower, so that the cooling of the current-conducting component is improved. As the cooling tower is an integral part of the housing part that forms the cooling duct, the number of components is reduced so that production is simplified and thus more cost-effective.

Preferably, the cooling duct and/or the cavity in the cooling tower are enclosed on all sides. That is to say, they are integrated into the housing part in such a way that they are surrounded on all sides by the material of the housing. This eliminates the need for costly sealing measures. It is only necessary to ensure that the cooling medium can be applied to the cooling duct via at least one inlet. The cooling medium then reaches the cavity of the cooling tower via the cooling duct. Preferably, at least one outlet is further provided to discharge the coolant from the cooling duct or the housing part. The fact that the cooling medium flows through the housing part means that heat dissipation and thus cooling can be further optimized.

The cavity formed in the cooling tower is preferably connected to the cooling duct in such a way that the coolant can flow in at one point and flow out again at another point. In this way, the exchange of coolant in the cavity is ensured so that heat is optimally dissipated. The cooling duct can be guided over the cavity so that it forms a kind of loop in the area of the cavity. In this case, the cooling medium is forcibly guided so that fresh cooling medium flows through the cavity.

Furthermore, the housing part that forms the cooling duct and the cooling tower is preferably produced in an additive manufacturing process, preferably in a 3D printing method. In an additive manufacturing process, in particular in a 3D printing method, cavities may be easily formed to simplify the production of the housing part.

According to a preferred embodiment of the invention, the cooling tower is surrounded at its free end by a sleeve made of an electrically insulating material. The sleeve forms an insulating component with the aid of which a current-conducting component resting on the cooling tower can be electrically insulated from the housing part. Preferably, the sleeve has a collar section that is offset radially inwards. This allows a positive connection between the sleeve and the current-conducting component, in particular if a recess is formed in the current-conducting component for receiving the collar section of the sleeve.

Furthermore, it is proposed that the current-conducting component rests on the sleeve, preferably on the collar section that is offset radially inwards, and is fastened to the cooling tower by means of a fastener, for example a screw. The fastener is preferably guided through the current-conducting component, preferably through a recess that receives the collar section of the sleeve. The fastener can then be connected, preferably screwed, to the cooling tower through the collar section. The current-conducting component is then electrically isolated from the cooling tower or the housing part forming the cooling tower via the sleeve.

In further developments of the invention, it is proposed that a cover plate made of an electrically insulating material is inserted between the current-conducting component and the fastener to electrically insulate the current-conducting component from the fastener. Preferably, the cover plate has a collar via which it is connected to the collar section of the sleeve arranged on the cooling tower. The connection may be, for example, a plug-in, clamp, press, or screw connection. In the case of a screw connection, the collar of the cover plate and the collar section of the sleeve are each to be provided with a thread. Regardless of the specific type of connection, the collar can be used to create a positive connection between the cover plate and the collar section of the sleeve, so that the cover plate is held securely-even before the fastener is inserted. This simplifies assembly.

Advantageously, a washer is inserted between the cover plate and the fastener. This particularly applies if the fastener is a screw. This is because the washer ensures an even distribution of force when tightening the screw, so that the cover plate is not damaged.

Furthermore, the cooling tower preferably has a bore on the end face for receiving the fastener. As the cooling tower is not in contact with the current-conducting component, the fastener does not have to be electrically insulated from the cooling tower or the housing part. If the cooling tower is electrically insulated from the current-conducting component by means of a sleeve with a collar section that is offset radially inwards and/or the fastener is electrically insulated from the current-conducting component by means of a cover plate with a collar, the collar section and/or the collar also ensure that the fastener does not come into contact with the current-conducting component. If the fastener is a screw, it is further proposed that the bore for receiving the fastener is designed as a threaded hole, at least in sections. The screw may then be screwed into the threaded hole.

The bore for receiving the fastener preferably has no connection to the cavity formed in the cooling tower for receiving the cooling medium. This eliminates measures for sealing the cavity.

In addition, a method for producing a power distribution unit is proposed, which comprises a housing which has a housing part that forms a cooling duct, to which a cooling medium can be applied, and at least one cooling tower extending substantially perpendicularly to the cooling duct, for receiving a current-conducting component, in particular a bus bar. In the method, the housing part is produced in an additive manufacturing process, in particular in a 3D printing method.

The additive manufacturing method, in particular a 3D printing method, simplifies the formation of cavities in the housing part so that it is particularly easy to produce. The fact that the cooling duct and the cooling tower are integral components of the housing part reduces the number of components. Furthermore, costly assembly steps may be omitted. Sealing measures are also not necessary.

After the production of the housing part, a sleeve made of an electrically insulating material is placed on the cooling tower. The current-conducting component is placed on the sleeve and fastened to the cooling tower by means of a fastener, preferably a screw. In this case, a cover plate made of an electrically insulating material and/or a washer is inserted between the fastener and the current-conducting component. The sleeve and-if present-the cover plate can be used to provide the necessary electrical insulation. Preferably, the sleeve has a collar section that is offset radially inwards, which passes through the current-conducting component so that the fastener does not come into contact with the current-conducting component. If a cover plate is provided, this can comprise a collar via which the cover plate can be connected to the sleeve, in particular the collar section of the sleeve.

The fastener is preferably inserted into a bore of the cooling tower through the current-conducting component. If the fastener is a screw, it is screwed into the bore. The bore is designed as a threaded hole at least in sections for this purpose.

### BRIEF DESCRIPTION OF THE DRAWINGS

A preferred embodiment of a power distribution unit for a fuel cell system according to the invention is explained in more detail below with reference to the accompanying drawings. Shown are:

FIG. 1 a perspective view of an opened power distribution unit according to the invention in the area of a plurality of cooling towers with bus bars connected,

FIG. 2 a longitudinal section through a cooling tower of the power distribution unit of FIG. 1,

FIG. 3 a perspective view of a housing part of the power distribution unit of FIG. 1 forming the cooling towers; and

FIG. 4 a cross section through the housing part of the power supply unit of FIG. 1 in the area of the cooling duct and the cooling towers.

### DETAILED DESCRIPTION

The illustration of FIG. 1 shows a sectional interior view of a power distribution unit 1 according to the invention. Current-conducting components 6 in the form of bus bars that rest on cooling towers 5 and are fastened to them in the form of screws using fasteners 10 can be seen. Cover washers 11 and washers 13 are inserted between the fasteners 10 and the current-conducting components 6. A sleeve 8 is arranged between each of the current-conducting components 6 and the cooling towers 5. The sleeves 8 and the cover plates 11 are made of an electrically insulating material and thus serve to electrically insulate the current-conducting components 6 from the cooling towers 5 on the one hand and from the fastener 10 on the other hand.

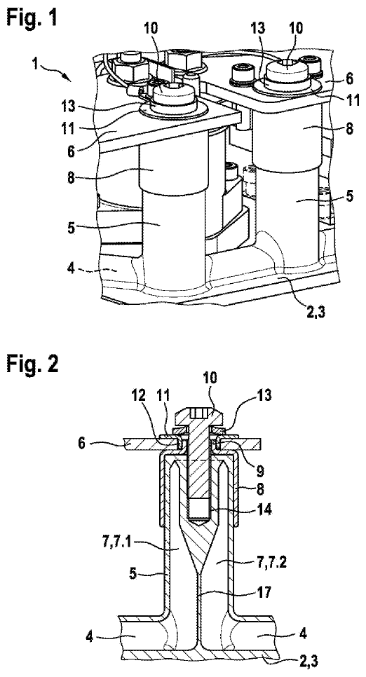

As can be seen in FIG. 2 in particular, wherein only one cooling tower is shown in FIG. 2, the cooling towers 5 are formed by a housing part 3 of a housing 2 of the power distribution unit 1. The housing part 3 further forms a cooling duct 4, via which cavities 7 formed in the cooling towers 5 can be applied with a cooling medium. The cooling medium is thus brought close to the current-conducting components 6 so that they are cooled more optimally. The fact that the cooling duct 4 and the cooling towers 5 are integrated into the housing part 3 reduces the number of components. As a result, the cost of assembling the power distribution unit 1 is also reduced. At the same time, the cooling duct 4 and the cooling towers 5 are guaranteed to be highly leak-proof without any further sealing measures.

The housing part 3 shown can be produced in particular in an additive manufacturing process, for example in a 3D printing method, so that the cooling duct 4 and the cooling towers 5 are particularly easy to produce.

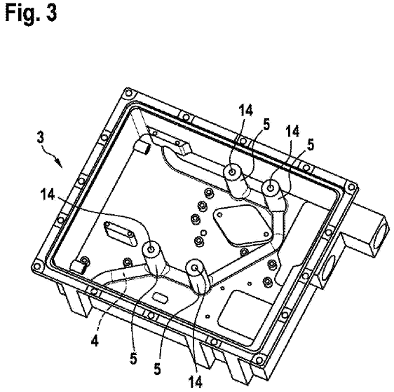

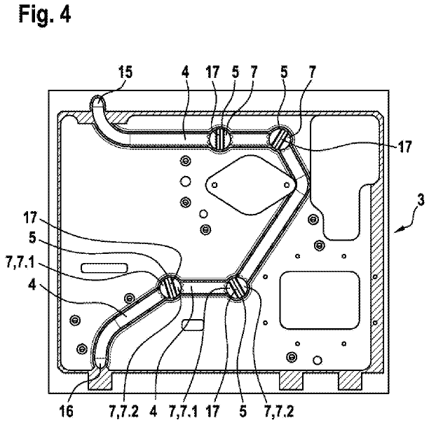

The housing part 3 is shown in a single representation in FIGS. 3 and 4. Overall, the housing part 3 forms a cooling duct 4 and four cooling towers 5. The number is only an example and may therefore vary. As can be seen in FIG. 3 in particular, the cooling towers 5 each have a bore 14 on the end face for receiving a fastener 10, which in particular may be a screw. The bore 14 does not have any connection to the cavity 7 of the respective cooling tower 5 (see also FIG. 2).

It can be seen from FIG. 4 that the cooling duct 4 comprises an inlet 15 and an outlet 16 for the cooling medium. The cooling duct 4 extends over the cavities 7 formed in the cooling towers 5 so that the exchange of cooling medium is ensured. For this purpose, the cavities 5 are separated into two subspaces 7.1, 7.2 in the area of the cooling duct 4 by an intermediate wall 17 (also see FIG. 2).

The electrical insulation of the current-conducting components 6 from the housing part 3 is explained in more detail with reference to FIG. 2. This shows that the sleeves 8 each have a collar section 9 that is offset radially inwards and which passes through the respective exposed current-conducting component 6. The cover plates 11 resting on the outside of the current-conducting components 6 each have a collar 12, via which the cover plates 11 are connected to the collar sections 9 of the sleeves 8. The collar sections 9 and the collars 12 ensure that neither the cooling towers 5 nor the fasteners 10 come into contact with a current-conducting component 6.

1. A power distribution unit (1) for a fuel cell system, comprising a housing (2) which has a housing part (3) that forms a cooling duct (4), to which a cooling medium can be applied, and at least one cooling tower (5), extending substantially perpendicularly to the cooling duct (4), for receiving a current-conducting component (6), wherein a cavity (7) is formed in the cooling tower (5) and is connected to the cooling duct (4) such that the cooling medium can also be applied to the cavity (7).

2. The power distribution unit (1) according to claim 1,
wherein the cooling duct (4) and/or the cavity (7) in the cooling tower (5) are enclosed on all sides.

3. The power distribution unit (1) according to claim 1,
wherein the housing part (3) has been produced in an additive manufacturing process.

4. The power distribution unit (1) according to claim 1,
wherein the cooling tower (5) is surrounded at a free end by a sleeve (8) made of an electrically insulating material.

5. The power distribution unit (1) according to claim 4,
wherein the current-conducting component (6) rests on the sleeve (8) and is fastened to the cooling tower (5) by a fastener (10).

6. The power distribution unit (1) according to claim 5,
wherein between the current-conducting component (6) and the fastener (10), a cover plate (11) made of an electrically insulating material is inserted.

7. The power distribution unit (1) according to claim 5,
wherein a washer (13) is inserted between the cover plate (11) and the fastener (10).

8. The power distribution unit (1) according to claim 5,
wherein the cooling tower (5) comprises a bore (14) on an end face for receiving the fastener (10).

9. A method for producing a power distribution unit (1), comprising a housing (2) which has a housing part (3) that forms a cooling duct (4), to which a cooling medium can be applied, and at least one cooling tower (5) extending substantially perpendicularly to the cooling duct (4), for receiving a current-conducting component (6), wherein the housing part (3) is produced in an additive manufacturing method.

10. The method according to claim 9,
wherein a sleeve (8) made of an electrically insulating material is placed on the cooling tower (5), the current-conducting component (6) is placed on the sleeve (8) and fastened to the cooling tower (5) by a fastener (10), wherein a cover plate (11) made of an electrically insulating material and/or a washer (13) is inserted between the fastener (10) and the current-conducting component (6).

11. The power distribution unit (1) according to claim 1, wherein the current-conducting component (6) is a bus bar.

12. The power distribution unit (1) according to claim 3, wherein the housing part (3) is a 3D printed part.

13. The power distribution unit (1) according to claim 4, wherein the sleeve (8) comprises a collar section (9) that is offset radially inwards.

14. The power distribution unit (1) according to claim 5, wherein the fastener (10) is a screw.

15. The power distribution unit (1) according to claim 6, wherein the cover plate (11) is connected to a collar section (9) of the sleeve (8) arranged on the cooling tower (5) via a collar (12).

16. The power distribution unit (1) according to claim 8, wherein the bore (14) is at least partially threaded.

17. The method as claimed in claim 9, wherein the current-conducting component (6) is a bus bar.

18. The method as claimed in claim 9, wherein the housing part (3) is produced in a 3D printing method.

19. The method as claimed in claim 10, wherein the fastener (10) is a screw.
